(19) United States
(12) Patent Application Publication
(10) Pub. No.: US 2022/0244320 A1
(43) Pub. Date: Aug. 4, 2022

(54) LOW COST METHOD-B HIGH VOLTAGE ISOLATION SCREEN TEST

(71) Applicant: TEXAS INSTRUMENTS INCORPORATED, Dallas, TX (US)

(72) Inventor: Thomas Dyer Bonifield, Dallas, TX (US)

(21) Appl. No.: 17/512,382

(22) Filed: Oct. 27, 2021

Related U.S. Application Data
(60) Provisional application No. 63/143,203, filed on Jan. 29, 2021.

(51) Int. Cl. G01R 31/52; G01R 31/14

(52) U.S. Cl. CPC G01R 31/52; G01R 31/14

(57) ABSTRACT

A method includes applying an AC test voltage signal to a terminal of an electronic device, the AC test voltage signal having a test frequency of 100 Hz or more, sensing a current signal of the electronic device during application of the AC test voltage signal, and identifying the electronic device as passing an isolation test in response to the current signal being less than a current threshold. After identifying the electronic device as passing the isolation test, the method includes applying a second AC test voltage signal to the terminal of the electronic device, the second AC test voltage signal having a second test frequency of 100 Hz or more, measuring a partial discharge of the electronic device during application of the second AC test voltage signal, and identifying the electronic device as passing a partial discharge test in response to the partial discharge being less than a threshold.

### CROSS-REFERENCE TO RELATED APPLICATION

This application claims priority to and benefit of U.S. Provisional Patent Application Ser. No. 63/143,203, filed on Jan. 29, 2021, and titled “Low Cost High Voltage Test For High Voltage Isolation Products”, the contents of which are hereby fully incorporated by reference.

### BACKGROUND

High voltage packaged electronic devices includes circuits that operate at different voltage levels with high voltage isolation between different voltage domains. For example, high voltage capacitors can provide isolation between transmit and receive circuits that operate in different voltage domains. Other isolation circuits include transformers or optical isolation components. For all of these high voltage isolation technologies, the isolation circuit requires high voltage testing of the isolation. While integrated isolation circuitry can be tested during manufacturing, package level final testing insertion for high voltage isolation screening is costly due to long test times required by standards.

### SUMMARY

In one aspect, a method includes applying an AC test voltage signal to a terminal of an electronic device, the AC test voltage signal having a test frequency of 100 Hz or more, sensing a current signal of the electronic device during application of the AC test voltage signal, and identifying the electronic device as passing an isolation test in response to the current signal being less than a current threshold.

In another aspect, a method includes applying an AC test voltage signal to a terminal of an electronic device, the AC test voltage signal having a test frequency of 100 Hz or more, measuring a partial discharge of the electronic device during application of the AC test voltage signal, and in response to the partial discharge being less than a partial discharge threshold, identifying the electronic device as passing a partial discharge test.

In another aspect, a system includes a test terminal, an AC supply, and a signal processing system. The test terminal is adapted to be coupled to a terminal of an electronic device. The AC supply has an output coupled to the test terminal. The AC supply is configured to apply a first AC test voltage signal to the test terminal for a first duration of 0.1 seconds or more and 0.5 seconds or less. The first AC test voltage signal has a test frequency of 100 Hz or more and the first AC test voltage signal has an amplitude of 1 kV RMS or more and 10 kV RMS or less. The signal processing system has a voltage sensing input and a current sensing input. The voltage sensing input is coupled to the test terminal, and the current sensing input is coupled to a current sensor to sense a current signal of the electronic device during application of the first AC test voltage signal. The signal processing system is configured to identify the electronic device as passing an isolation test in response to the current signal being less than a current threshold. The AC supply is configured to, after the electronic device is identified as passing the isolation test, apply a second AC test voltage signal to the test terminal for a second duration of 0.1 seconds or more and 0.5 seconds or less, the second AC test voltage signal having a second test frequency of 100 Hz or more, and the second AC test voltage signal having an amplitude of 1 kV RMS or more and 5 kV RMS or less. The signal processing system is configured to measure a partial discharge of the electronic device during application of the second AC test voltage signal and identify the electronic device as passing a partial discharge test in response to the partial discharge being less than a partial discharge threshold.

### BRIEF DESCRIPTION OF THE DRAWINGS

FIG. 1 is a flow diagram of a method for manufacturing an electronic device.

FIG. 2 is a perspective view of a packaged electronic device

FIG. 3 is a schematic diagram of a final device test system configured to test isolation of a packaged electronic devices using a high frequency bipolar AC test signal.

FIG. 4 is a schematic diagram of a final device test system configured to test isolation of a packaged electronic devices using a high frequency unipolar AC test signal.

FIG. 5 is a graph showing a test voltage waveform illustrating the amplitudes of the high frequency AC applied voltage in an isolation test.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating.

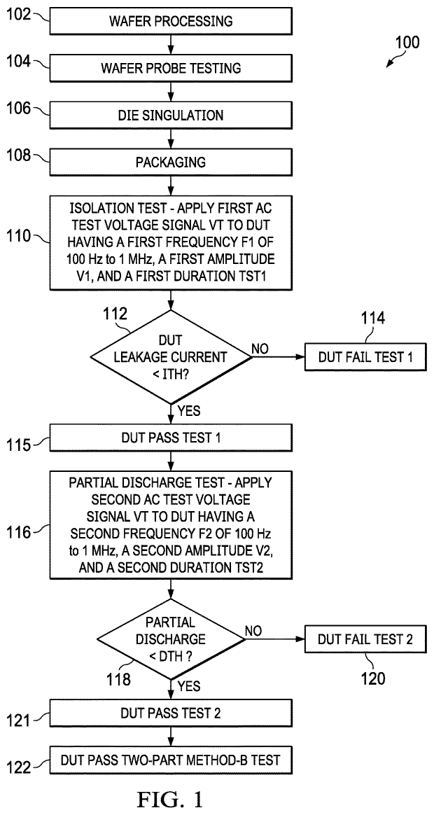

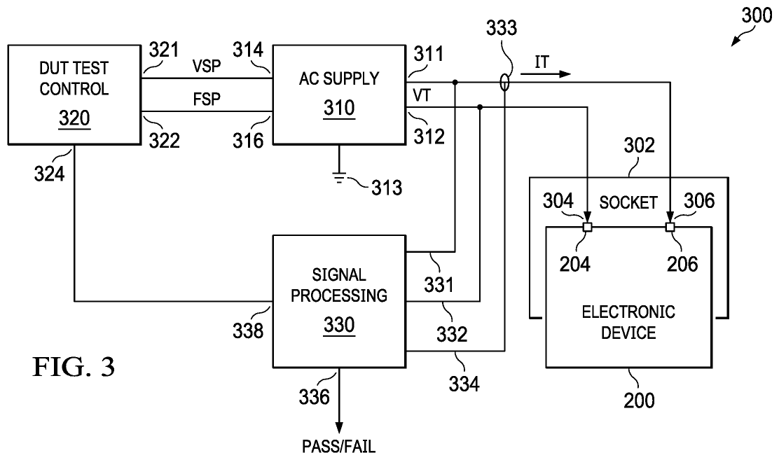

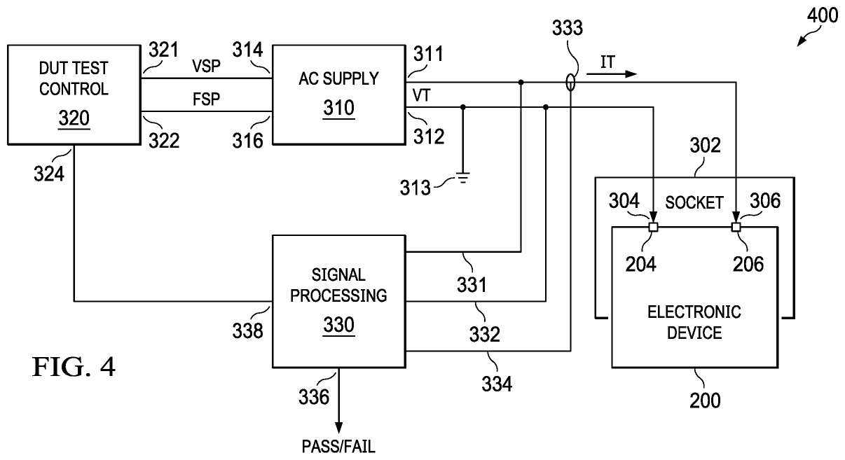

FIG. 1 shows a method 100 for manufacturing an electronic device. The method 100 includes wafer processing at 102, wafer probe testing at 104, die simulation at 106, and packaging at 108. The example method 100 includes two-step isolation certification testing at final test of packaged electronic devices following packaging at 108. The isolation testing in one example is implemented to test high voltage reinforced isolation or basic isolation pursuant to VDE 0884-11 and supporting IEC standards such as IEC 60747-17 or IEC 60664-1 or modifications thereof. In one example illustrated and described below, the isolation testing is performed in two steps with an electronic device inserted into a socket or other fixture of a final test system, examples of which are shown in FIGS. 3 and 4 below, such as a Teradyne eagle test systems ETS-88 configured for high throughput, low-cost test for single site, multi-site and index parallel test applications, available from Teradyne, Inc. of North Reading, Mass. The two-step testing includes an initial isolation test and a partial discharge test. Another example implements a single step test which combines the isolation test and the partial discharge test during the same high voltage wave form. As previously discussed, the cost of package level final testing for high voltage isolation screening varies with the length of time required for the test.

The method 100 provides cost-effective high-volume testing for integrated circuit or other electronic device manufacturing applications to screen out packaged electronic devices or individual circuits of a processed wafer that do not meet applicable isolation standards. In the illustrated examples, high frequency unipolar and/or bipolar AC test voltage signals are applied by an AC supply to a terminal of a tested electronic device (e.g., referred to as a device under test or DUT) to provide high dv/dt voltage stress to evaluate the device isolation at wafer or device testing. The use of high frequency AC test voltage signals facilitates reliable screening of devices with respect to expected isolation performance, while shortening testing times. Reduced test time, in turn, reduces manufacturing cost of electronic devices.

The example two-step isolation testing begins at 110 in FIG. 1 with an isolation test (TEST 1), in which a first AC test voltage signal V1 is applied to a terminal of the electronic device. The first AC test voltage signal VT has an amplitude V1 and a first test frequency F1 of 100 Hz or more. In one example, the first test frequency F1 is 1 MHz or less, such as 100 kHz or less. In one example, the first test frequency F1 is 1 kHz or more and 10 kHz or less. In another example, the first test frequency F1 is 1.5 kHz or more and 2.5 kHz or less, such as approximately 2.0 kHz, within a tolerance of the test equipment used. In one implementation, the first AC test voltage signal VT has an amplitude V1 of 5 kV RMS or more and 20 kV RMS or less. In another example, the first AC test voltage signal VT has an amplitude V1 of 3 kV RMS or more and 10 kV RMS or less, such as approximately 7 kV RMS, within a tolerance of the test equipment used. In one example, the first AC test voltage signal VT is applied to the terminal of the electronic device for a first duration TST1 of 0.01 seconds or more and 0.5 seconds or less, such as approximately 0.1 seconds, within a tolerance of the test equipment used. In one implementation, the first AC test voltage signal VT is a sine wave. In another implementation, the first AC test voltage signal VT is a square wave. This provides enhanced dv/dt of the applied signal to test the device isolation with a more demanding wave form which is more representative of applications and in a shortened isolation test. In one example, the first AC test voltage signal VT is applied as a bipolar signal between first and second terminals of the tested device (e.g., FIG. 3 below). In another example, the first AC test voltage signal VT is applied as a unipolar square wave signal.

A current signal of the tested device is sensed during application of the first AC test voltage signal VT, which represents a leakage current of the tested device in response to application of the first AC test voltage signal VT. A determination is made at 112 as to whether the leakage current is less than a current threshold ITH. If the leakage current is greater than or equal to the current threshold ITH (NO at 112), the tested device (DUT) is identified as failing the first test. In one example, the testing of the device is terminated in response to the determination that the device has failed the first test. Otherwise (YES at 112), the method 100 continues with identifying the electronic device as passing the isolation test at 115 in response to the current signal IT being less than the current threshold ITH.

The method 100 continues at 116 after the electronic device has been identified as passing the isolation test. At 116, the method further includes applying a second AC test voltage signal (also labeled VT) to the terminal of the electronic device. The second AC test voltage signal VT in one example has a second amplitude V2 and a second test frequency F2 of 100 Hz or more. In one example, the second test frequency F2 is 1 MHz or less, such as 100 kHz or less. In one example, the second test frequency F2 is equal to the first test frequency F1. In another example, the first and second test frequencies are different. The second test frequency F2 in one example is 1 kHz or more and 10 kHz or less. In another example, the second test frequency F2 is 1.5 kHz or more and 2.5 kHz or less, such as approximately 2.0 kHz, within a tolerance of the test equipment used. In one example, the second AC test voltage signal VT has a second amplitude V2 of 1 kV RMS or more and 5 kV RMS or less, such as approximately 3 kV RMS. In one implementation, the second AC test voltage signal VT is a sine wave. In another implementation, the second AC test voltage signal VT is a square wave. In these or another example, the second AC test voltage signal VT is applied to the terminal of the electronic device 200 for a duration TST2 of 0.01 seconds or more and 0.5 seconds or less, such as approximately 0.1 seconds, within a tolerance of the test equipment used.

The method 100 also includes measuring a partial discharge of the electronic device and 118 during application of the second AC test voltage signal VT. In one example, the partial discharge is measured at 118 by sensing the current signal IT of the electronic device 200 during application of the second AC test voltage signal VT, filtering the current signal IT to remove the second test frequency F2 content of the current signal IT to create a filtered signal, and integrating the filtered signal to generate a partial discharge signal that represents the partial discharge of the tested electronic device during application of the second AC test voltage signal VT. A determination is made at 118 as to whether the partial discharge of the tested device is less than a partial discharge threshold DTH. If the measured electronic device partial discharge is greater than or equal to the threshold DTH (NO at 118), the tested device is identified at 120 as having failed the partial discharge test (e.g., partial discharge detected, TEST2). Otherwise, in response to the partial discharge being less than the partial discharge threshold DTH (YES at 118), identifying 121 the electronic device 200 as passing a partial discharge test, and the tested device is identified at 122 as having passed the two-step isolation test (e.g., two-part IEC Method-B test).

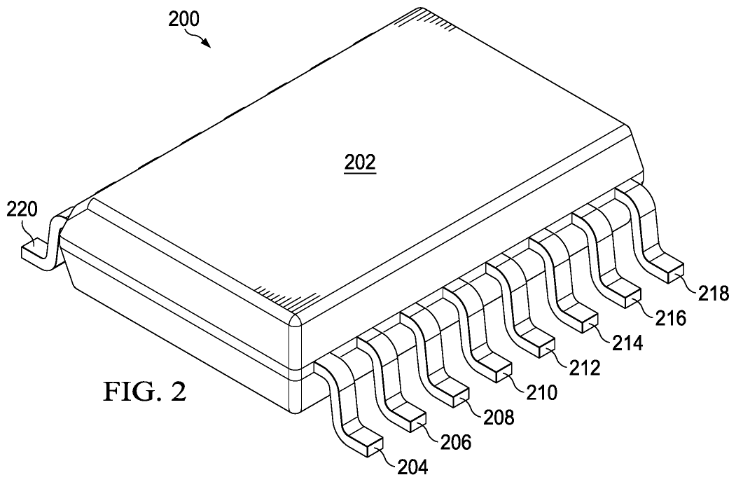

Referring now to FIGS. 2-5, FIG. 2 shows a packaged electronic device 200 fabricated according to the method 100, illustrated after packaging at 108. The electronic device 200 in this example is an integrated circuit with a small outline integrated circuit (SOIC) package structure 202 (e.g., molded material), as well as gull wing leads 204, 206, 208, 210, 212, 214, 216, 218, and 220 that extend outward and downward from opposite sides of the package structure 202 for soldering to a host printed circuit board (PCB, not shown). The electronic device 200 also includes one or more semiconductor dies (not shown) having electronic components (e.g., resistors, capacitors, transistors, etc.).

The electronic device 200 in one implementation is a multi-die packaged electronic device having multiple semiconductor dies (not shown), for example, operating at two or more different voltage levels or domains, with isolation circuitry (e.g., capacitors, transformers, optocouplers, etc.) providing isolation barriers between different voltage domains. In one example, the electronic device 200 has internal isolation components for communications between first and second semiconductor dies, for example, including 5 V wireless area network (WAN) connections through an isolation circuit that includes capacitors, transformers, optocouplers, etc. In another example, the electronic device 200 includes a high voltage isolation barrier (e.g., 1000 V RMS) for use in a motor control application. In another example, the electronic device 200 includes circuitry for electric vehicle (EV) or hybrid electric vehicle (HEV) charging circuitry, with 1000 V DC isolation barrier between high and low voltage domains, including semiconductor dies and/or other circuit components with high voltage (HV) withstanding voltage ratings (e.g., HV capacitors, HV transformers, optical isolation components, etc.).

FIG. 3 shows a final device test system 300 configured to test isolation of the packaged electronic device 200 using high frequency bipolar AC test signals according to the method 100. The system 300 is illustrated as a final test system for testing packaged electronic devices 200.

The illustrated system 300 includes a socket 302 with test terminals 304 and 306 adapted to engage with, and provide electrical connection to, respective leads 204 and 206 of the electronic device 200 when inserted into the socket 302. The system 300 also includes an AC supply 310 having an output with first and second output terminals 311 and 312, respectively. The output terminals 311 and 312 of the AC supply 310 are coupled to the respective test terminals 306 and 304 of the socket 302. The AC supply 310 in this example has a ground or reference terminal coupled to a circuit ground 313 of the test system 300. The AC supply 310 also includes one or more control inputs configured to receive respective control signals to set an output voltage VT and frequency (e.g., the first and second test frequencies F1 and F2). In one implementation, the AC supply 310 includes a communications interface (not shown) that allows the AC supply 310 to receive setpoint voltage and frequency values for communications messaging.

In the illustrated example, the AC supply 310 includes a first input 314 that receives a setpoint voltage signal or value VSP, and a second input 316 that receives a setpoint frequency signal or value FSP. In operation, the AC supply 310 provides an AC test voltage signal VT at the output 311, 312 having an amplitude that corresponds to the setpoint voltage signal VSP and a frequency that corresponds to the setpoint frequency signal FSP. In addition, the AC supply 310 in one implementation is configured to selectively provide the AC test voltage signal VT as a sine wave or a square wave, for example, according to a signal waveform signal or value.

The test system 300 also includes a test controller 320 (e.g., labeled DUT TEST CONTROL) with a first control output 321 coupled to the first input 314 of the AC supply 310 to provide the setpoint voltage signal or value VSP to the AC supply 310. The test controller 320 in this example also includes a second control output 322 coupled to the second input 316 to provide the setpoint frequency signal FSP to the AC supply 310. In one implementation, the test controller 320 includes an input 324.

The test system 300 in this example also includes a signal processing system 330 having a voltage sensing input with a terminal 331 coupled to the AC supply output terminal 311, and a second sensing input terminal 332 coupled to the AC supply output terminal 312. The signal processing system 330 also includes a current sensing input 334 that is coupled to a current sensor 333 to sense a current signal IT of the electronic device 200 during application of the first AC test voltage signal VT. The signal processing system 330 also includes an output 338 that is coupled to the input 324 of the test controller 320, for example, to communicate sensed and/or measured or computed signals or values to the test controller 320. The test controller 320 and the signal processing system 330 in one example include analog circuitry as well as one or more logic or processor circuits that are programmed or programmable to implement the test functions for final testing of the packaged electronic device 200. In addition, the test controller 320 in one example interfaces with multiple AC supplies 310 and associated signal processing systems 330 in order to perform concurrent testing of multiple packaged electronic devices 200 installed in respective sockets 302.

In operation generally according to the method 100 above, the AC supply 310 applies the first AC test voltage signal VT as a bipolar (e.g., differential) voltage signal to (e.g., across) the output terminals 311 and 312 and the test terminals 304 and 306 for the first duration TST1 of 0.01 seconds or more and 0.5 seconds or less. In operation, moreover, the AC supply 310 operates according to voltage and frequency setpoints received at the respective inputs 314 and 316 to provide the first AC test voltage signal VT having a test frequency F1 of 100 Hz or more and an amplitude V1 of 3 kV RMS or more and 10 kV RMS or less, for example, as described above in connection with FIG. 1. In operation, the signal processing system 333 measures (e.g., senses) the current IT of the electronic device 200 during application of the first AC test voltage signal VT and determines whether the device current IT is less than the current threshold ITH. In response to the current signal IT being less than the current threshold ITH, the signal processing system 333 identifies the electronic device 200 as passing the isolation test (e.g., TEST1). In one implementation, the signal processing system 330 has an output 336 provides a PASS/FAIL signal indicating whether the tested electronic device 200 has passed or failed one or both of the isolation test and the partial discharge test, for example, to an external host system (not shown).

In addition, after the electronic device 200 is identified as passing the isolation test, the AC supply 310 applies the second AC test voltage signal VT to the test terminals 304, 306 for the second duration TST2 of 0.01 seconds or more and 0.5 seconds or less. The second AC test voltage signal VT in this example has a second test frequency F2 of 100 Hz or more and an amplitude V2 of 1 kV RMS or more and 5 kV RMS or less, according to adjusted voltage and/or frequency setpoint signals or values from the test controller 320. The signal processing system 330 measures the partial discharge of the electronic device 200 during application of the second AC test voltage signal VT. In response to the partial discharge being less than the partial discharge threshold DTH, the signal processing system 330 identifies the electronic device 200 as passing the partial discharge test and provides a pass/fail indication to the test controller 320 and/or at the output 336.

In one implementation, as discussed above in connection with FIG. 1, the signal processing system 330 measures the device partial discharge by sensing the current signal IT of the electronic device 200 during application of the second AC test voltage signal VT, filtering the current signal IT to remove the second test frequency F2 content of the current signal IT to create a filtered signal, and integrating the filtered signal to generate a partial discharge signal that represents the partial discharge of the tested electronic device during application of the second AC test voltage signal VT. In one example, the signal processing system 330 includes analog circuitry to implement the current signal filtering and integration to create an analog partial discharge signal that is compared to an analog voltage that represents the partial discharge threshold DTH. In another implementation, the signal processing system 330 includes analog-to-digital conversion circuitry and performs the filtering and/or integration, as well as the threshold comparison, in the digital domain.

FIG. 4 shows another final device test system 400 configured to test isolation of the packaged electronic device 200 using a high frequency unipolar AC test signal. The test system 400 includes the socket 302, AC supply 310, test controller 320, and signal processing system 330 and operates generally as discussed above in connection with FIG. 3. In this example, however, the AC supply 310 is connected to provide the AC test voltage signal VT as a unipolar (e.g., single ended) voltage signal to the terminals 304 and 306 of the socket 302. In this example, the output terminal 312 of the AC supply 310 is coupled to the circuit ground 313 of the test system 400.

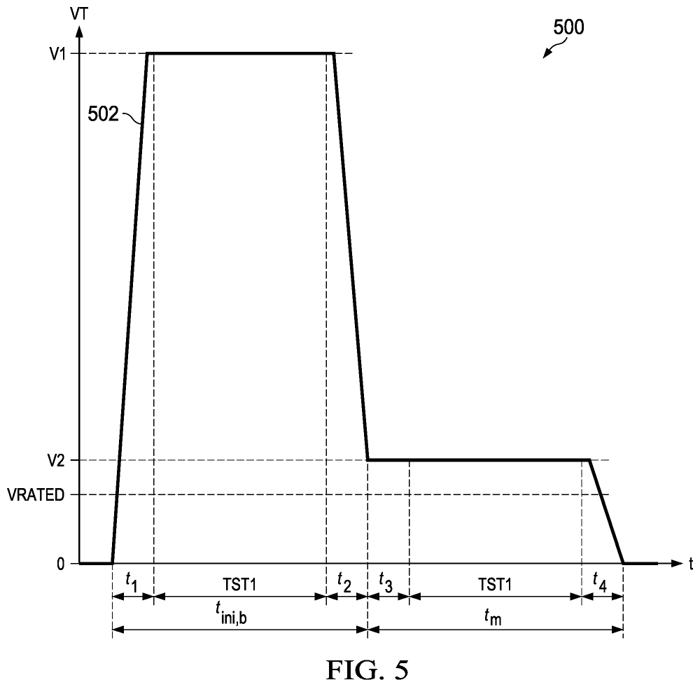

FIG. 5 shows a graph 500 including a test voltage signal waveform 502 that represents the amplitude of an AC test voltage signal VT in one implementation of the two-step isolation test in operation of the test system 300 or 400 above. The AC test voltage signal VT (curve 502) in this example starts at 0 V RMS, and the AC supply 310 ramps the AC voltage amplitude up to the first amplitude V1 (e.g., approximately 7 kV RMS, 10 kV peak-peak) at a fairly high dv/dt during a first time period t₁ (e.g., approximately 0.03 seconds). The AC supply 310 maintains the AC test voltage signal VT at the first amplitude V1 for the first duration TST1 of 0.01 seconds or more and 0.5 seconds or less, such as approximately 0.1 seconds, within a tolerance of the test system 300, 400, and then ramps the AC test voltage signal VT down to the second amplitude V2 during a second time period t₂ (e.g., approximately 0.03 seconds). In this example, the duration t_{ini,b} of the first test is t₁+TST1+t₂ (e.g., approximately 0.36 seconds). This is significantly faster than performing the isolation test using an applied 60 Hz AC high voltage signal with a duration of approximately 1.2 seconds, thereby reducing test time and manufacturing cost significantly.

The partial discharge test (e.g., TEST2) in the example of FIG. 5 is also much quicker than testing using 60 Hz applied signals. In the example of FIG. 5, the second test includes a settling time period t₃ (e.g., approximately 0.03 seconds) to allow the AC test voltage signal VT to stabilize at the second amplitude V2, and the AC supply 310 maintains the AC test voltage signal VT at the amplitude V2 for the second duration TST2 of 0.01 seconds or more and 0.5 seconds or less, such as approximately 0.1 seconds, within a tolerance of the test system 300, 400, and then ramps the AC test voltage signal VT down to zero during a fourth time period t₄ (e.g., approximately 0.03 seconds). In this example, the duration tₘ of the partial discharge test is t₃+TST2+t₄ (e.g., approximately 0.36 seconds). Again, this is a significant test time reduction and cost reduction compared to partial discharge testing using 60 Hz applied signals. In one example, 60 Hz high voltage Method-B testing involves testing for 60 cycles of the AC sine waveform for evaluating high voltage stress performance of a tested device, which corresponds to each test step maintaining the 60 Hz applied signal for 1 second, whereas the described examples facilitate testing for 60 or even more cycles (e.g., 600 cycles) of the AC sine wave or square wave using high voltage, high frequency AC test voltage signals VT for both isolation testing and partial discharge testing. In other implementations, a single test is performed using such a high voltage, high frequency AC test voltage signal VT for either isolation testing or partial discharge testing. The described method 100 and the illustrated test systems 300, 400 facilitate achieving the desired isolation and/or partial discharge testing to screen packaged devices 200 within a much shorter test time to significantly reduce manufacturing cost. The use of high frequency AC test voltage signals VT also provides the benefit of enhanced dv/dt compared with 60 Hz sine wave testing, and the use of square waves in certain examples provides further enhancement with respect to dv/dt of the applied AC test voltage signal VT. For example, as shown in the following Table 1.

| | | Embodiment | Embodiment |
|---|---|---|---|
| | Current | #1 | #2 |
| V1 (Vrms, Vpeak) | 7000, 10000 | 7000, 10000 | 7000, 10000 |
| Vl HV frequency, | 60 Hz sine | 2,000 Hz sine | 2,000 Hz sine |
| wave form | wave | wave | wave |
| V2 (Vrms,Vpeak) | 3000, 4200 | 3000, 4200 | 3000, 3000 |
| V2 HV frequency, | 60 Hz sine | 2,000 Hz sine | 2,000 Hz bipolar |
| wave form | wave | wave | sqaure wave |
| V2 rise/fall, usec | 4244 | 127 | 0.03 |
| dV2/dt, V/nsec | 2 | 33 | 200 |
| T1 | 0.1 | 0.03 | 0.03 |
| Tst1 | 1 | 0.3 | 0.3 |
| st1 · cycles | 60 | 600 | 600 |
| T2 | 0.1 | 0.03 | 0.03 |
| T3 | 0.1 | 0.03 | 0.03 |
| Tst2 | 1 | 0.3 | 0.3 |
| st1 # cycles | 60 | 600 | 600 |
| T4 | 0.1 | 0.03 | 0.03 |
| Tindex | 1 | 1 | 1 |
| Test time | 3.4 | 1.72 | 1.72 |
| Partial Discharge | std | better - more | better - more |
| test coverage | | cycles, higher | cycles, very high |
| | | dV/dt | dV/dt |

The described examples can also be employed in combination with other cost reduction enhancements, including use of lower cost test equipment, testing more devices concurrently, and further reducing test times be reducing settling times.

Modifications are possible in the described examples, and other implementations are possible, within the scope of the claims.

What is claimed is:

1. A method for manufacturing an electronic device, the method comprising:
applying an AC test voltage signal to a terminal of the electronic device, the AC test voltage signal having a test frequency of 100 Hz or more;
sensing a current signal of the electronic device during application of the AC test voltage signal; and
in response to the current signal being less than a current threshold, identifying the electronic device as passing an isolation test.

2. The method of claim 1, wherein:
the test frequency is 1 kHz or more and 10 kHz or less; and
the AC test voltage signal has an amplitude of 1 kV RMS or more and 20 kV RMS or less.

3. The method of claim 2, wherein:
the test frequency is 1.5 kHz or more and 2.5 kHz or less; and
the AC test voltage signal has an amplitude of 3 kV RMS or more and 10 kV RMS or less.

4. The method of claim 3, wherein the AC test voltage signal is applied to the terminal of the electronic device for a duration of 0.01 seconds or more and 0.5 seconds or less.

5. The method of claim 3, wherein the AC test voltage signal is a sine wave.

6. The method of claim 3, wherein the AC test voltage signal is a square wave.

7. The method of claim 3, wherein the AC test voltage signal is applied as a bipolar signal between the terminal and a second terminal of the electronic device.

8. The method of claim 3, further comprising:
after identifying the electronic device as passing the isolation test, applying a second AC test voltage signal to the terminal of the electronic device, the second AC test voltage signal having a second test frequency of 100 Hz or more;
measuring a partial discharge of the electronic device during application of the second AC test voltage signal; and
in response to the partial discharge being less than a partial discharge threshold, identifying the electronic device as passing a partial discharge test.

9. The method of claim 8, wherein measuring the partial discharge of the electronic device comprises:
sensing the current signal of the electronic device during application of the second AC test voltage signal;
filtering the current signal to remove the second test frequency content of the current signal to create a filtered signal; and
integrating the filtered signal to generate a partial discharge signal that represents the partial discharge of the electronic device during application of the second AC test voltage signal.

10. The method of claim 8, wherein the second test frequency is equal to the test frequency.

11. The method of claim 10, wherein the second AC test voltage signal has an amplitude of 1 kV RMS or more and 5 kV RMS or less.

12. The method of claim 11, wherein the second AC test voltage signal is applied to the terminal of the electronic device for a duration of 0.01 seconds or more and 0.5 seconds or less.

13. The method of claim 11, wherein the second AC test voltage signal is a sine wave.

14. The method of claim 11, wherein the second AC test voltage signal is a square wave.

15. The method of claim 1, further comprising:
after identifying the electronic device as passing the isolation test, applying a second AC test voltage signal to the terminal of the electronic device, the second AC test voltage signal having a second test frequency of 100 Hz or more;
measuring a partial discharge of the electronic device during application of the second AC test voltage signal; and
in response to the partial discharge being less than a partial discharge threshold, identifying the electronic device as passing a partial discharge test.

16. A method for manufacturing an electronic device, the method comprising:
applying an AC test voltage signal to a terminal of the electronic device, the AC test voltage signal having a test frequency of 100 Hz or more;
measuring a partial discharge of the electronic device during application of the AC test voltage signal; and
in response to the partial discharge being less than a partial discharge threshold, identifying the electronic device as passing a partial discharge test.

17. The method of claim 16, wherein measuring the partial discharge of the electronic device comprises:
sensing a current signal of the electronic device during application of the AC test voltage signal;
filtering the current signal to remove the test frequency content of the current signal to create a filtered signal; and
integrating the filtered signal to generate a partial discharge signal that represents the partial discharge of the electronic device during application of the AC test voltage signal.

18. The method of claim 16, wherein the AC test voltage signal has an amplitude of 1 kV RMS or more and 5 kV RMS or less.

19. The method of claim 16, wherein the AC test voltage signal is applied to the terminal of the electronic device for a duration of 0.01 seconds or more and 0.5 seconds or less.

20. A system for testing an electronic device, the system comprising:
a test terminal adapted to be coupled to a terminal of the electronic device;
an AC supply having an output, the output coupled to the test terminal, the AC supply configured to apply a first AC test voltage signal to the test terminal for a first duration of 0.01 seconds or more and 0.5 seconds or less, the first AC test voltage signal having a test frequency of 100 Hz or more, and the first AC test voltage signal having an amplitude of 3 kV RMS or more and 10 kV RMS or less;
a signal processing system having a voltage sensing input and a current sensing input, the voltage sensing input coupled to the test terminal, and the current sensing input coupled to a current sensor to sense a current signal of the electronic device during application of the first AC test voltage signal, the signal processing system configured to, in response to the current signal being less than a current threshold, identify the electronic device as passing an isolation test;
the AC supply configured to, after the electronic device is identified as passing the isolation test, apply a second AC test voltage signal to the test terminal for a second duration of 0.01 seconds or more and 0.5 seconds or less, the second AC test voltage signal having a second test frequency of 100 Hz or more, and the second AC test voltage signal having an amplitude of 1 kV RMS or more and 5 kV RMS or less;
the signal processing system configured to: measure a partial discharge of the electronic device during application of the second AC test voltage signal; and in response to the discharge being less than a partial discharge threshold, identify the electronic device as passing a partial discharge test.
